(19) United States
(12) Patent Application Publication
(10) Pub. No.: US 2020/0075740 A1
(43) Pub. Date: Mar. 5, 2020

(54) AMPLIFYING DEVICE AND RADIO COMMUNICATION DEVICE

(71) Applicant: FUJITSU LIMITED, Kawasaki-shi (JP)

(72) Inventors: Masato Nishimori, Machida (JP); Ikuo Soga, Isehara (JP); Tatsuya Hirose, Yokohama (JP); Yoichi Kawano, Setagaya (JP)

(73) Assignee: FUJITSU LIMITED, Kawasaki-shi (JP)

(21) Appl. No.: 16/548,900

(22) Filed: Aug. 23, 2019

(30) Foreign Application Priority Data
Aug. 28, 2018 (JP) 2018-159295

(51) Int. Cl. H01L 29/423; H01L 29/417; H01L 23/482; H03F 3/24; H04B 1/04

(52) U.S. Cl. CPC H01L 29/4238; H01L 29/4175; H01L 2924/0002; H03F 3/24; H04B 1/0483; H01L 23/4824

(57) ABSTRACT

An amplifying device includes: a comb-shaped transistor that includes a comb-shaped source electrode having a plurality of source fingers; one or more resistors connected between the source electrode and a ground; and a plurality of capacitors connected between the source electrode and the ground, wherein the capacitors are separated from each other and arranged in a direction in which the source fingers are arranged.

### CROSS-REFERENCE TO RELATED APPLICATION

This application is based upon and claims the benefit of priority of the prior Japanese Patent Application No. 2018-159295, filed on Aug. 28, 2018, the entire contents of which are incorporated herein by reference.

### FIELD

The embodiments relate to an amplifying device and a radio communication device.

### BACKGROUND

While the amount of communication data in radio communication increases in recent years, a radio communication device is known, which includes an amplifying device that amplifies a signal to increase transmission power of the radio communication device. There is an example in which a multi-finger field effect transistor (FET) having a comb-shaped electrode structure is used in an amplifying device (refer to, for example, Japanese Laid-open Patent Publication No. 2001-44448).

### SUMMARY

According to an aspect of the embodiments, an amplifying device includes: a comb-shaped transistor that includes a comb-shaped source electrode having a plurality of source fingers; one or more resistors connected between the source electrode and a ground; and a plurality of capacitors connected between the source electrode and the ground, wherein the capacitors are separated from each other and arranged in a direction in which the source fingers are arranged.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a circuit diagram illustrating a configuration of a current feedback bias circuit;

FIG. 2 is a plan view illustrating a configuration of the current feedback bias circuit;

FIG. 3 is a diagram illustrating a configuration of a radio communication device;

FIG. 4 is a plan view illustrating a configuration of an amplifying device according to a first embodiment;

FIG. 5 is a plan view illustrating a configuration of an amplifying device according to a second embodiment;

FIG. 6 is a plan view illustrating a configuration of an amplifying device according to a third embodiment;

FIG. 7 is a diagram illustrating an equivalent circuit of the amplifying device according to the first embodiment;

FIG. 8 is a diagram illustrating an equivalent circuit of the amplifying device according to the third embodiment;

FIG. 9 is a plan view illustrating a configuration of an amplifying device according to a fourth embodiment;

FIG. 10 is a plan view illustrating a configuration of an amplifying device according to a fifth embodiment; and

FIG. 11 is a diagram illustrating an equivalent circuit of an amplifying device according to a sixth embodiment.

### DESCRIPTION OF EMBODIMENTS

In an amplifying device that outputs a radio frequency (RF) signal, however, Idq drift in which an idling current Idq varies due to RF stress upon the output of the RF signal may occur. The idling current Idq indicates a current (drain current) that flows to a drain of the amplifying device in a state (idling state) in which an RF signal is not input to the amplifying device. When the idling current Idq varies, an input and output characteristic (amplification characteristic) of the amplifying device may be degraded and a distortion within a signal output from the amplifying device may increase, for example.

According to an aspect of the present disclosure, an amplification characteristic may be improved.

Hereinafter, embodiments of the disclosure are described.

Each of amplifying devices according to the embodiments is used, for example, in a radio communication device such as a base station. Each of the amplifying devices according to the embodiments may be formed by a monolithic microwave integrated circuit (MMIC) obtained by forming elements such as a transistor, a capacitor, and a resistor on a single semiconductor substrate, for example. Forming an amplifying device by an MMIC is effective to downsize the high-frequency and high-output amplifying device.

Each of the amplifying devices according to the embodiments is, for example, a power amplifier formed using a transistor such as a nitrogen gallium (GaN) device. The GaN device has a wider band gap and higher mobility than other semiconductor devices (for example, a silicon lateral-diffused metal oxide semiconductor (Si-LDMOS), a gallium arsenide field effect transistor (GaAs-FET), and the like). Thus, the GaN device has an excellent high frequency output characteristic.

In a transistor such as the GaN device, however, Idq drift in which an idling current Idq varies due to RF stress upon the output of an amplified transmission signal may occur. In this case, the idling current Idq is a current (drain current) that flows from a drain to which a power supply voltage is applied to a source from which an amplified transmission signal is output in a state (idling state) in which a transmission signal to be amplified is not input to a gate of the transistor.

When the idling current Idq varies, an amplification characteristic of the transistor included in the amplifying device may be degraded and a distortion within a signal output from the amplifying device may increase. A variation in a gain of the amplifying device and a variation in the phase of a signal output from the amplifying device are large, especially during a variation in the idling current Idq. Thus, even when distortion compensation is executed by digital pre-distortion (DPD), the accuracy of the compensation is easily reduced.

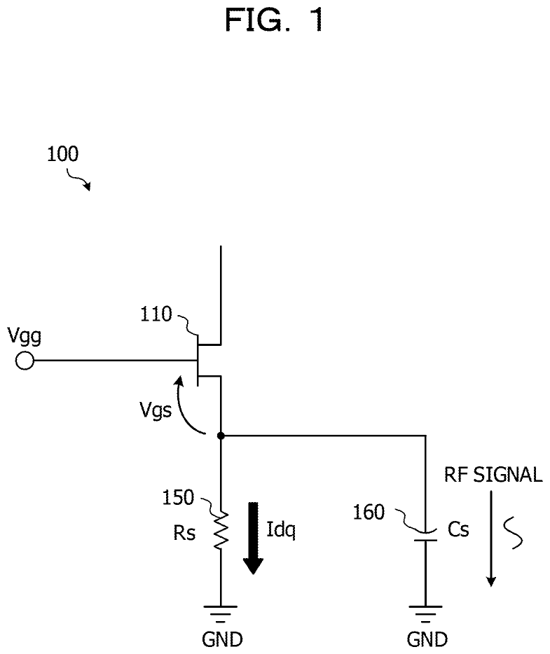

To suppress the variation in the idling current Idq, a current feedback bias circuit 100 in which a resistor 150 and a capacitor 160 are connected in parallel between a source of a transistor 110 and the ground (GND) is effective, as illustrated in FIG. 1. In a configuration illustrated in FIG. 1, when a gate bias is Vgg, a resistance value of the resistor 150 is Rs, and a drain current that flows in the resistor 150 is Idq, a voltage Vgs between a gate of the transistor 110 and the source of the transistor 110 is Vgg−Rs×Idq.

When the drain current Idq varies, the voltage Vgs varies to suppress the variation in the drain current Idq. When the drain current Idq decreases, the voltage Vgs increases to increase the drain current Idq. When the drain current Idq increases, the voltage Vgs decreases to decrease the drain current Idq. Thus, the variation in the idling current may be suppressed.

The capacitor 160 having a capacity value Cs is inserted between the source of the transistor 110 and the ground so that the source of the transistor 110 is grounded in a high-frequency manner. By inserting the capacitor 160, a decrease in the gain of the transistor 110 is suppressed.

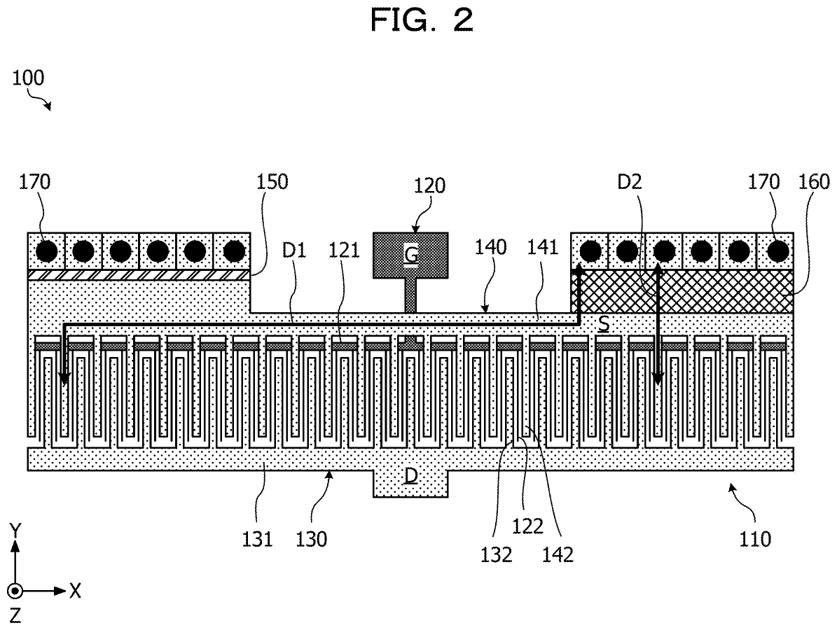

FIG. 2 is a plan view illustrating a configuration of the current feedback bias circuit 100 illustrated in FIG. 1. The current feedback bias circuit 100 includes the comb-shaped transistor 110, the resistor 150, and the capacitor 160. The transistor 110 includes a source electrode 140 and a drain electrode 130 that are arranged opposite to each other in a comb-shaped manner. The comb-shaped transistor 110 includes the comb-shaped source electrode 140, the comb-shaped drain electrode 130, and a comb-shaped gate electrode 120.

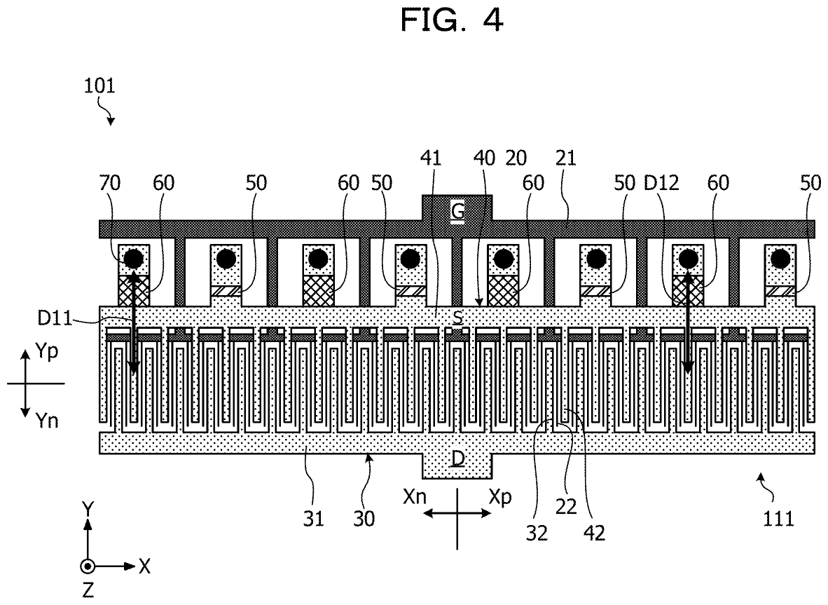

In FIG. 2, G, S, and D indicate the gate of the transistor 110, the source of the transistor 110, and a drain of the transistor 110. In addition, an X axis direction, a Y axis direction, and a Z axis direction indicate a direction parallel to an X axis, a direction parallel to a Y axis, and a direction parallel to a Z axis, respectively. The X axis, the Y axis, and the Z axis are perpendicular to each other. The same applies to FIGS. 4, 5, 6, 9, and 10.

The source electrode 140 includes a source wiring 141 and multiple source fingers 142 extending from the source wiring 141. The drain electrode 130 includes a drain wiring 131 and multiple drain fingers 132 extending from the drain wiring 131. The gate electrode 120 includes a gate wiring 121 and multiple gate fingers 122 extending from the gate wiring 121. Each of the multiple gate fingers 122 is inserted between a source finger 142 among the multiple source fingers 142 and a drain finger 132 among the multiple drain fingers 132. The resistor 150 is connected to the ground via multiple via holes 170 and exists between the source wiring 141 and the ground. The capacitor 160 is connected to the ground via multiple via holes 170 and exists between the source wiring 141 and the ground.

However, in the comb-shaped transistor in which the source electrode and the drain electrode are arranged opposite to each other in the comb-shaped manner, in a state in which the resistor 150 and the capacitor 160 are simply connected to the source electrode 140, as a range in which the fingers formed in comb shapes are arranged in the X axis direction is larger, a high-frequency characteristic may be more degraded. This is due to the fact that distances between the source fingers 142 and the capacitor 160 vary depending on the positions of the source fingers 142. For example, a distance D2 from a source finger 142 existing on the same side as the capacitor 160 with respect to a central portion of the source electrode 140 in the X axis direction to the capacitor 160 is shorter than a distance D2 from a source finger 142 existing on the opposite side to the capacitor 160 with respect to the central portion of the source electrode 140 in the X axis direction to the capacitor 160. Since the phases of high-frequency signals that pass through the source fingers 142 are different for the source fingers 142, a synthetic loss of the high-frequency signals may occur and the high-frequency characteristic (amplification characteristic) may be degraded.

Thus, each of the amplifying devices according to the embodiments has a simple configuration to suppress a difference between the phases of high-frequency signals in a comb-shaped transistor. Even when the comb-shaped transistor is large in size, an excellent high-frequency characteristic may be secured. Hereinafter, the amplifying devices according to the embodiments and a radio communication device having any of the amplifying devices are described.

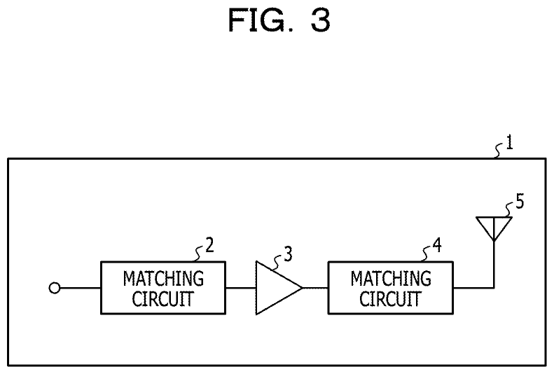

FIG. 3 is a diagram illustrating a configuration of a radio communication device according to the embodiments. The radio communication device 1 illustrated in FIG. 3 intermittently transmits a radio wave from an antenna 5 based on a high-frequency signal amplified by an amplifying device 3 according to any of the embodiments. The radio communication device 1 executes radio communication using a Time Division Duplex (TDD) scheme in which a signal is transmitted and received at predetermined repetitive time intervals, for example.

Specific examples of the radio communication device 1 are a radio base station, a mobile phone, a smartphone, and an Internet of Things (IoT) device. The radio communication device 1, however, is not limited to the specific examples. The radio communication device 1 includes the antenna 5 and the amplifying device 3.

A transmission signal amplified by the amplifying device 3 is supplied to the antenna 5. The antenna is an element that transmits a radio wave corresponding to the supplied transmission signal. The antenna 5 may be one of multiple antenna elements forming an array antenna.

The amplifying device 3 amplifies an input transmission signal and outputs the amplified transmission signal to the antenna 5. Since the transmission signal amplified by the amplifying device 3 is supplied to the antenna 5, and a radio wave corresponding to the transmission signal is transmitted from the antenna 5, radio communication may be executed.

The radio communication device 1 may include a matching circuit 2 for matching an input section of the radio communication device 1 with an input section of the amplifying device 3 and may include a matching circuit 4 for matching an output section of the amplifying device 3 with the antenna 5.

FIG. 4 is a plan view illustrating a configuration of an amplifying device according to a first embodiment. The amplifying device 101 illustrated in FIG. 4 is applicable to the amplifying device 3 illustrated in FIG. 3. The amplifying device 101 includes a comb-shaped transistor 111, multiple resistors 50, and multiple capacitors 60. The transistor 111 includes a comb-shaped source electrode 40 having multiple source fingers 42. The resistors 50 are connected between the source electrode 40 and the ground. The capacitors 60 are connected between the source electrode 40 and the ground. Each of the multiple resistors 50 is connected to the ground via a via hole 70 that is among multiple via holes 70 and corresponds to the resistor 50. Similarly, each of the multiple capacitors 60 is connected to the ground via a via hole 70 that is among the multiple via holes 70 and corresponds to the capacitor 60.

In the amplifying device 101 according to the first embodiment, the multiple capacitors 60 are separated from each other and arranged in the X axis direction in which the multiple source fingers 42 are arranged. Since the multiple capacitors 60 that are connected in parallel between the source electrode 40 and the ground are separated from each other and arranged in the X axis direction in which the multiple source fingers 42 are arranged, differences between the phases of high-frequency signals, which pass through the source fingers 42, between the source fingers 42 are reduced. A variation in distances from the source fingers 42 to the capacitors 60 in the configuration illustrated in FIG. 4 is smaller, compared with a case in which only a single capacitor 60 is connected between the source electrode 40 and the ground. Thus, even when the size of the comb-shaped transistor 111 in the X axis direction in which the fingers formed in a comb shape are arranged is increased, a synthetic loss of high-frequency signals is suppressed. Accordingly, a high-frequency characteristic (amplification characteristic) of the amplifying device 101 is improved. As a result, it may be possible to suppress a distortion within a signal output from a drain electrode 30 of the amplifying device 101.

In FIG. 4, the number of capacitors 60 is 4. In the first embodiment, however, the number of capacitors 60 may be 2 or more as long as a requested amplification characteristic is satisfied. In FIG. 4, the number of resistors 50 is 4. In the first embodiment, however, the number of resistors 50 may be 1 or more as long as the requested amplification characteristic is satisfied.

In FIG. 4, the multiple capacitors 60 include 2 capacitors 60 arranged on a side Xp with respect to a central portion of the source electrode 40 in the X axis direction and include 2 capacitors 60 arranged on a side Xn with respect to the central portion in the X axis direction. In this case, a variation in a difference between a distance D12 between an arbitrary capacitor 60 arranged on the side Xp and an arbitrary source finger 42 arranged on the side Xp and a distance D11 between an arbitrary capacitor 60 arranged on the side Xn and an arbitrary source finger 42 arranged on the side Xn is small. Thus, even when the size of the comb-shaped transistor 111 in the X axis direction in which the fingers formed in the comb shape are arranged is increased, a synthetic loss of high-frequency signals is suppressed. Accordingly, an excellent high-frequency characteristic (amplification characteristic) of the amplifying device 101 is obtained.

In FIG. 4, the number of capacitors 60 arranged on the side Xp is 2. In the first embodiment, however, the number of capacitors 60 arranged on the side Xp may be 1 or more as long as the requested amplification characteristic is satisfied. In FIG. 4, the number of capacitors 60 arranged on the side Xn is 2. In the first embodiment, however, the number of capacitors 60 arranged on the side Xn may be 1 or more as long as the requested amplification characteristic is satisfied.

The configuration illustrated in FIG. 4 according to the first embodiment is described in more detail below.

The amplifying device 101 includes the comb-shaped transistor 111, the multiple resistors 50, and the multiple capacitors 60. In the transistor 111, the source electrode and the drain electrode are arranged opposite to each other in a comb-shaped manner. The comb-shaped transistor 111 is a multi-finger FET and includes the comb-shaped source electrode 40, the comb-shaped drain electrode 30, and a comb-shaped gate electrode 20.

The source electrode 40 includes a band-like source wiring 41 linearly extending in the X axis direction and the multiple source fingers 42 extending from the source wiring 41 toward a side Yn in the Y axis direction. The drain electrode 30 includes a band-like drain wiring 31 linearly extending in the X axis direction and multiple drain fingers 32 extending from the drain wiring 31 toward a side Yp in the Y axis direction.

The gate electrode 20 includes a ladder-like gate wiring 21 extending in the X axis direction and multiple gate fingers 22 extending from the gate wiring 21 toward the side Yn in the Y axis direction. Each of the multiple gate fingers 22 is inserted between a source finger 42 among the multiple source fingers 42 and a drain finger 32 that is among the multiple drain fingers 32 and adjacent to the source finger 42.

Each of the multiple resistors 50 is an element connected to the ground via a via hole 70, which is among the multiple via holes 70 and corresponds to the resistor 50. The multiple resistors 50 exist between the source wiring 41 and the ground. Each of the capacitors 60 is an element connected to the ground via a via hole 70, which is among the multiple via holes 70 and corresponds to the capacitor 60. The capacitors 60 exist between the source wiring 41 and the ground. The capacitors 60 are, for example, metal-insulator-metal (MIM) capacitors.

The resistors 50 and the capacitors 60 are alternately arranged. Since the resistors 50 and the capacitors 60 are alternately arranged, a variation in distances from the source fingers 42 to the capacitors 60 and distances from the source fingers 42 to the resistors 50 is small. Thus, even when the size of the comb-shaped transistor 111 in the X axis direction in which the fingers formed in the comb shape are arranged is increased, a synthetic loss of high-frequency signals is suppressed and an excellent high-frequency characteristic (amplification characteristic) of the amplifying device 101 is obtained. As a result, it may be possible to suppress a distortion within a signal output from the drain electrode 30 of the amplifying device 101.

In the first embodiment, as illustrated in FIG. 4, the resistors 50 and the capacitors 60 are alternately arranged one by one in the X axis direction. However, each of the resistors 50 may be arranged between adjacent capacitors 60. Each of the capacitors 60 may be arranged between adjacent resistors 50.

In FIG. 4, the resistors 50 are arranged at openings of the latter-shaped gate wiring 21, respectively. In the first embodiment, however, multiple resistors 50 may be arranged at each of the openings. In FIG. 4, the capacitors 60 are arranged at the openings of the latter-shaped gate wiring 21, respectively. In the first embodiment, however, multiple capacitors 60 may be arranged at each of the openings.

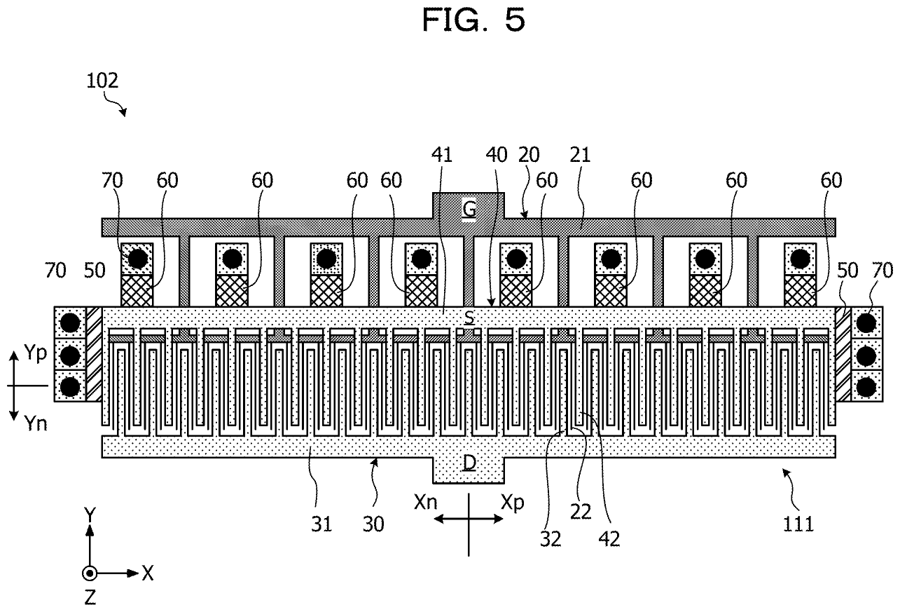

FIG. 5 is a plan view illustrating a configuration of an amplifying device according to a second embodiment. The amplifying device 102 illustrated in FIG. 5 is applicable to the amplifying device 3 illustrated in FIG. 3. A description of the same configurations and effects as those described in the first embodiment is omitted by employing the above description.

In the second embodiment, the number of resistors 50 is smaller than the number of capacitors 60. In FIG. 5, the number of resistors 50 is 2 and the number of capacitors 60 is 8. Resistor elements may not be connected on the side Yp of the source wiring 41, since an effect that affects differences between the phases of high-frequency signals between source fingers 42 corresponding to the resistor elements are smaller than an effect that affects differences between the phases of high-frequency signals between source fingers 42 corresponding to capacitors. For example, as illustrated in FIG. 5, resistors 50 may be connected at both ends of the source electrode 40 in the X axis direction. In this configuration, a larger number of capacitors 60 than that of capacitors 60 described in the first embodiment may be connected in parallel on the side Yp of the source wiring 41, and degradation in a high-frequency characteristic due to differences between the phases of high-frequency signals may be further suppressed.

In FIG. 5, one or more of the capacitors 60 arranged in the X axis direction may be replaced with one or more resistors 50. In FIG. 5, the resistors 50 are connected to both ends of the source electrode 40 in the X axis direction. A resistor 50 may be connected to only one of the ends of the source electrodes 40 in the X axis direction. In FIG. 5, the 2 resistors 50 may be replaced with 2 capacitors 60, and one or more of the 8 capacitors 60 may be replaced with one or more resistors 50.

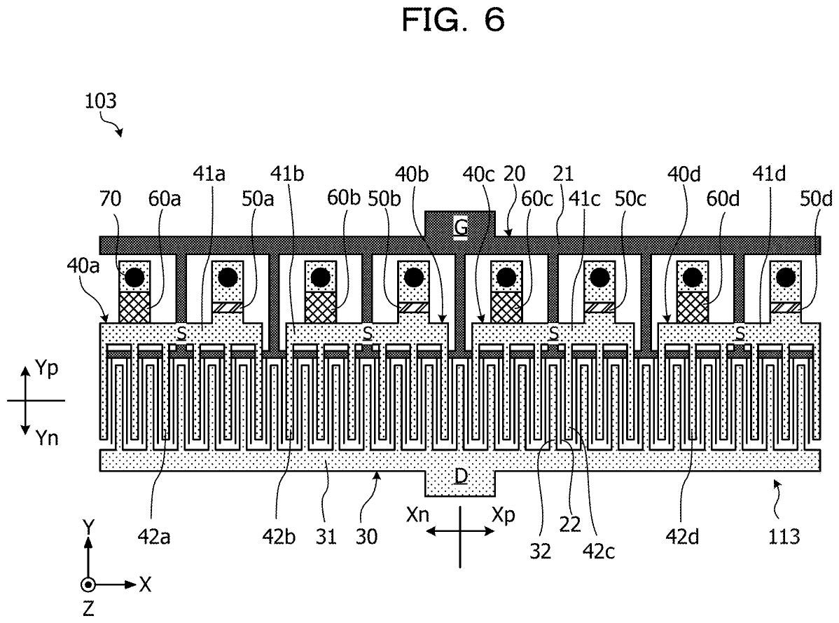

FIG. 6 is a plan view illustrating a configuration of an amplifying device according to a third embodiment. The amplifying device 103 illustrated in FIG. 6 is applicable to the amplifying device 3 illustrated in FIG. 3. A description of the same configurations and effects as those described in the first and second embodiments is omitted by employing the above descriptions.

In the third embodiment, as illustrated in FIG. 6, a source electrode 40 includes independent multiple source electrode portions 40a to 40d. For example, the source electrode 40 is divided into the multiple source electrode portions 40a to 40d, and a comb-shaped transistor 113 includes the multiple source electrode portions 40a to 40d.

Multiple capacitors 60 included in the amplifying device 103 include one or more capacitors connected to one or more source electrode portions that are among the source electrode portions 40a to 40d and correspond to the one or more capacitors 60. In FIG. 6, a capacitor 60a is connected to the source electrode portion 40a that is among the source electrode portions 40a to 40d and corresponds to the capacitor 60a, and a capacitor 60b is connected to the source electrode portion 40b that is among the source electrode portions 40a to 40d and corresponds to the capacitor 60b. A capacitor 60c is connected to the source electrode portion 40c that is among the source electrode portions 40a to 40d and corresponds to the capacitor 60c, and a capacitor 60d is connected to the source electrode portion 40d that is among the source electrode portions 40a to 40d and corresponds to the capacitor 60d. In FIG. 6, each of the capacitors is connected to a respective one of the source electrode portions. Multiple capacitors, however, may be connected to each of the source electrode portions.

Multiple resistors 50 included in the amplifying device 103 include one or more resistors connected to one or more source electrode portions that are among the source electrode portions 40a to 40d and correspond to the one or more resistors 50. In FIG. 6, a resistor 50a is connected to the source electrode portion 40a that is among the source electrode portions 40a to 40d and corresponds to the resistor 50a, and a resistor 50b is connected to the source electrode portion 40b that is among the source electrode portions 40a to 40d and corresponds to the resistor 50b. A resistor 50c is connected to the source electrode portion 40c that is among the source electrode portions 40a to 40d and corresponds to the resistor 50c, and a resistor 50d is connected to the source electrode portion 40d that is among the source electrode portions 40a to 40d and corresponds to the resistor 50d. In FIG. 6, each of the resistors is connected to a respective one of the source electrode portions. Multiple resistors, however, may be connected to each of the source electrode portions.

The source electrode portion 40a includes a band-like source wiring 41a linearly extending in the X axis direction and multiple source fingers 42a extending from the source wiring 41a toward the side Yn in the Y axis direction. The source electrode portion 40b includes a band-like source wiring 41b linearly extending in the X axis direction and multiple source fingers 42b extending from the source wiring 41b toward the side Yn in the Y axis direction. The source electrode portion 40c includes a band-like source wiring 41c linearly extending in the X axis direction and multiple source fingers 42c extending from the source wiring 41c toward the side Yn in the Y axis direction. The source electrode portion 40d includes a band-like source wiring 41d linearly extending in the X axis direction and multiple source fingers 42d extending from the source wiring 41d toward the side Yn in the Y axis direction.

The resistor 50a is connected between the source wiring 41a and the ground. The resistor 50b is connected between the source wiring 41b and the ground. The resistor 50c is connected between the source wiring 41c and the ground. The resistor 50d is connected between the source wiring 41d and the ground.

The capacitor 60a is connected between the source wiring 41a and the ground. The capacitor 60b is connected between the source wiring 41b and the ground. The capacitor 60c is connected between the source wiring 41c and the ground. The capacitor 60d is connected between the source wiring 41d and the ground.

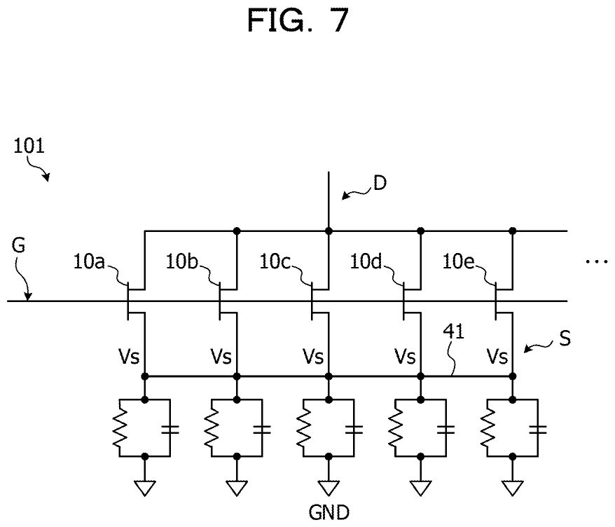

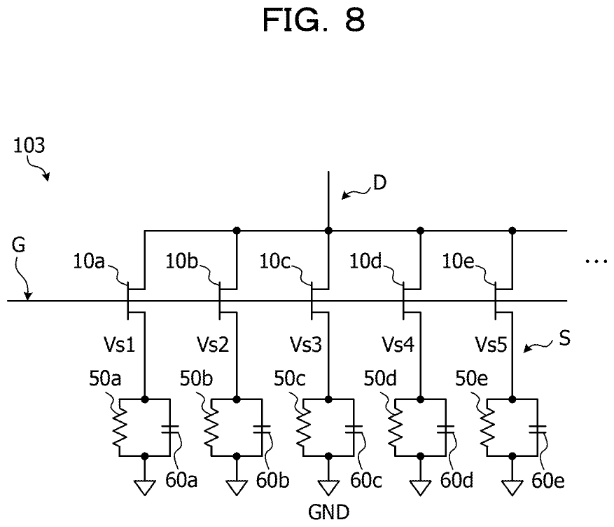

Differences between the third embodiment and the first embodiment are described below. FIG. 7 is a diagram illustrating an equivalent circuit of the amplifying device 101 illustrated in FIG. 4 according to the first embodiment. The comb-shaped transistor 111 of the amplifying device 101 is formed by multiple transistors (10a to 10e and the like) connected in parallel to each other, as illustrated in FIG. 7. FIG. 8 is a diagram illustrating an equivalent circuit of the amplifying device 103 illustrated in FIG. 6 according to the third embodiment. The comb-shaped transistor 113 of the amplifying device 103 is formed by multiple transistors (10a to 10e and the like) connected in parallel to each other, as illustrated in FIG. 8.

The current feedback bias circuit has a characteristic in which, as a variation in the drain current is larger, a variation in a potential of the source S increases to suppress the variation in the drain current. It is, therefore, desirable that a potential of a source S of a transistor significantly vary in the transistor in which an idling current significantly varies due to Idq drift or the like.

However, in a configuration illustrated in FIG. 7 according to the first embodiment, since the transistors are commonly connected to each other by the source wiring 41, potentials of sources S of the transistors are equal to Vs. Thus, even when variations in idling currents due to Idq drift or the like are different for the transistors, it is difficult to suppress the variations in the idling currents in the transistors. In a configuration illustrated in FIG. 8 according to the third embodiment, potentials Vs1 to Vs5 of sources S of the transistors independently vary. Thus, even when variations in idling currents due to Idq drift or the like are different for the transistors, it may be possible to individually suppress the variations in the idling currents in the transistors.

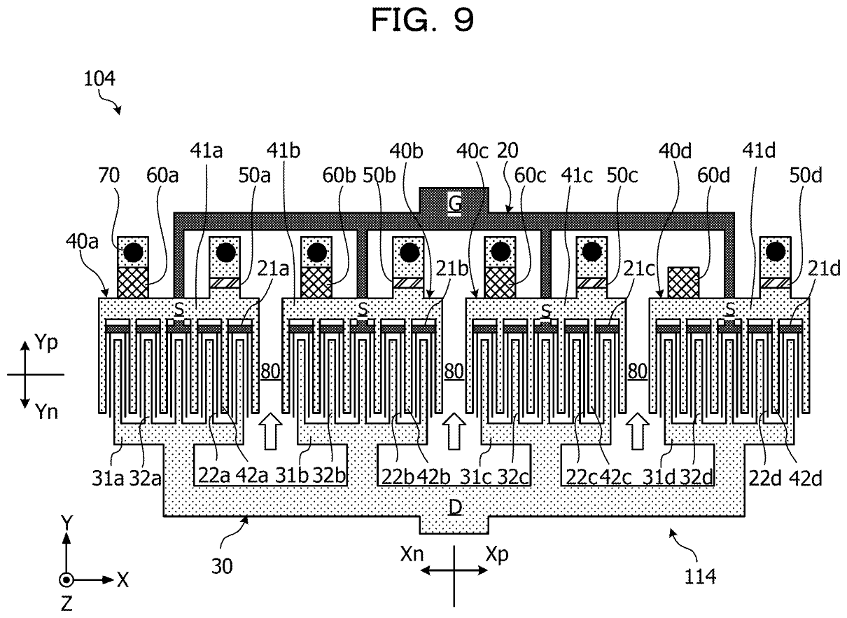

The following configuration is considered. In a comb-shaped transistor 114 included in an amplifying device 104 illustrated in FIG. 9 according to a fourth embodiment, a drain electrode 30 includes multiple independent drain electrode portions 31a to 31d, and a gate electrode 20 includes multiple independent gate electrode portions 21a to 21d. In the configuration illustrated in FIG. 9, however, spaces 80 exist between source electrode portions adjacent to each other in the X axis direction, and thus the area of the comb-shaped transistor (or the area of a combination of source, drain, and gate fingers) mounted in the same area is small. Thus, the third embodiment in which the drain wiring and the gate wiring are common to the multiple source electrode portions to improve a current density of the comb-shaped transistor is more preferable. The comb-shaped transistor 113 according to the third embodiment includes the drain wiring 31 common to the multiple source electrode portions 40a to 40d and the gate wiring 21 common to the multiple source electrode portions 40a to 40d.

The comb-shaped transistor 113 according to the third embodiment includes the drain electrode 30 having the drain wiring 31 common to the multiple source electrode portions 40a to 40d and the multiple drain fingers 32 extending directly from the drain wiring 31. In the third embodiment, the drain wiring 31 is a band-like conducting body linearly continuously extending in the X axis direction from the source electrode portion 40a located at an edge on the side Xn to the source electrode portion 40d located at an edge on the side Xp. The multiple drain fingers 32 extend directly from the drain wiring 31.

The comb-shaped transistor 113 according to the third embodiment includes the gate electrode 20 having the gate wiring 21 common to the multiple source electrode portions 40a to 40d and the multiple gate fingers 22 extending directly from the gate wiring 21. In the third embodiment, the gate wiring 21 is a band-like conducting body linearly continuously extending in the X axis direction from the source electrode portion 40a located at the edge on the side Xn to the source electrode portion 40d located at the edge on the side Xp. The multiple gate fingers 22 extend directly from the gate wiring 21.

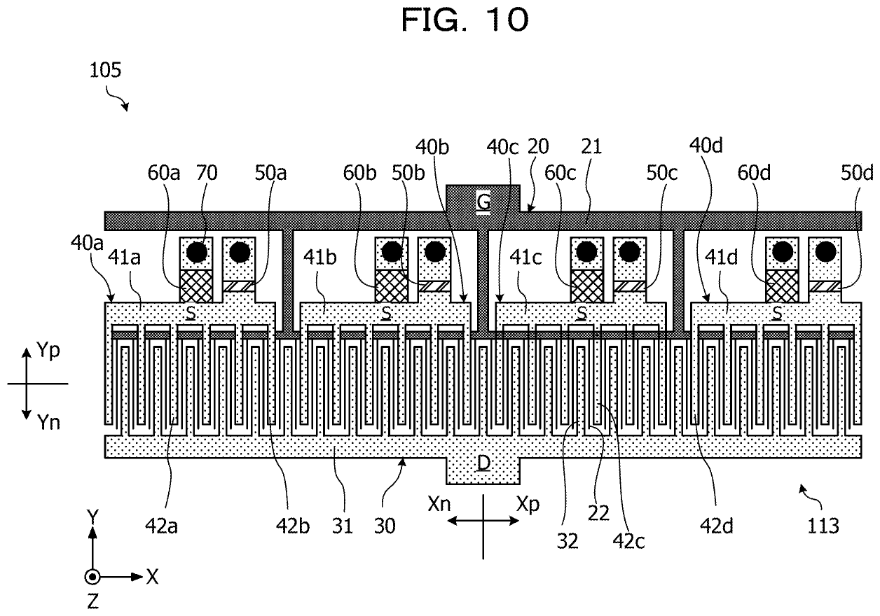

FIG. 10 is a plan view illustrating a configuration of an amplifying device according to a fifth embodiment. The amplifying device 105 illustrated in FIG. 10 is applicable to the amplifying device 3 illustrated in FIG. 3. A description of the same configurations and effects as those described in the first to fourth embodiments is omitted by employing the above descriptions.

In the fifth embodiment, as illustrated in FIG. 10, multiple capacitors 60 included in the amplifying device 105 include one or more capacitors 60 connected to a central portion of a source electrode portion in the X axis direction that is among the source electrode portions 40a to 40d and corresponds to the one or more capacitors 60. In FIG. 10, a capacitor 60a is connected to a central portion of the source electrode portion 40a in the X axis direction, and a capacitor 60b is connected to a central portion of the source electrode portion 40b in the X axis direction. In FIG. 10, a capacitor 60c is connected to a central portion of the source electrode portion 40c in the X axis direction, and a capacitor 60d is connected to a central portion of the source electrode portion 40d in the X axis direction. Thus, differences between the phases of high-frequency signals between the source fingers may be reduced by connecting the capacitors to the central portions of the source electrode portions.

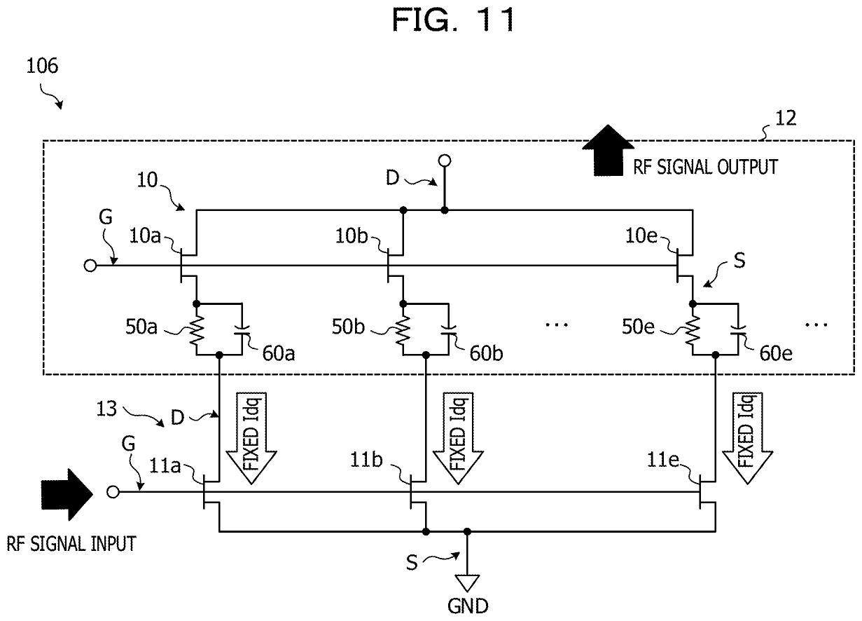

FIG. 11 is a plan view illustrating a configuration of an amplifying device according to a sixth embodiment. The amplifying device 106 illustrated in FIG. 11 is applicable to the amplifying device 3 illustrated in FIG. 3. A description of the same configurations and effects as those described in the first to fifth embodiments is omitted by employing the above descriptions.

The amplifying device 106 illustrated in FIG. 11 includes a second comb-shaped transistor 13 including a comb-shaped drain electrode having multiple drain fingers and a comb-shaped source electrode having multiple source fingers connected to the ground. The comb-shaped transistor 13 has the same configuration as any of the comb-shaped transistors described above in the embodiments. The comb-shaped transistor 13 is formed by multiple transistors 11a to 11e connected in parallel to each other. Resistors 50a to 50e and capacitors 60a to 60e are connected between a source electrode of a comb-shaped transistor 10 and the drain electrode of the comb-shaped transistor 13.

The amplifying device 106 includes a current source 12 having a parallel circuit with the resistors and the capacitors and the comb-shaped transistor 10 having the source electrode connected to the parallel circuit. The current source 12 has the same configuration as any of the amplifying devices described above in the embodiments.

The amplifying device 106 illustrated in FIG. 11 has a structure in which the resistors and the capacitors are arranged between source fingers of the upper cascode-connected transistor 10 and drain fingers of the lower transistor 13. According to the cascode configuration, a drain current of the upper comb-shaped transistor 10 serving as the current source 12 may be maintained at a fixed level, an excellent amplification characteristic of the amplifying device 106 may be obtained, and an operation of the amplifying device 106 may be stable.

Although the amplifying devices and the radio communication device are described in the embodiments, the disclosure is not limited to the aforementioned embodiments. Various changes and modifications such as a combination of a portion or all of an embodiment among the embodiments with a portion or all of another embodiment among the embodiments and the replacement of a portion or all of an embodiment among the embodiments with a portion or all of another embodiment among the embodiments may be made within the scope of the appended claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An amplifying device comprising:
a comb-shaped transistor that includes a comb-shaped source electrode having a plurality of source fingers;
one or more resistors connected between the source electrode and a ground; and
a plurality of capacitors connected between the source electrode and the ground,
wherein the capacitors are separated from each other and arranged in a direction in which the source fingers are arranged.

2. The amplifying device according to claim 1,
wherein the capacitors include a first capacitor and a second capacitor, the first capacitor being one or more capacitors arranged on one side of the source electrode with respect to a central portion of the source electrode in the direction, the second capacitor being one or more capacitors arranged on the other side of the source electrode with respect to the central portion in the direction.

3. The amplifying device according to claim 1,
wherein the source electrode includes a plurality of independent source electrode portions, and
wherein the capacitors include one or more capacitors connected to a first source electrode portion that is among the source electrode portions and corresponds to the one or more capacitors.

4. The amplifying device according to claim 3,
wherein the comb-shaped transistor includes
a drain electrode having a drain wiring common to the plurality of source electrode portions and a plurality of drain fingers extending from the drain wiring, and
a gate electrode having a gate wiring common to the plurality of source electrode portions and a plurality of gate fingers extending from the gate wiring.

5. The amplifying device according to claim 4,
wherein the capacitors include one or more capacitors connected to a central portion of a source electrode portion, which is among the source electrode portions and corresponds to the one or more capacitors, in the direction.

6. The amplifying device according to claim 1,
wherein the one or more resistors and the capacitors are alternately arranged.

7. The amplifying device according to claim 1,
wherein the number of resistors is smaller than the number of capacitors.

8. The amplifying device according to claim 1, further comprising:
a second comb-shaped transistor including a comb-shaped drain electrode having a plurality of drain fingers and a comb-shaped source electrode having a plurality of source fingers connected to the ground,
wherein the one or more resistors and the capacitors are connected between the source electrode of the comb-shaped transistor and the drain electrode of the second comb-shaped transistor.

9. A radio communication device comprising:
an antenna; and
an amplifying device that amplifies an input transmission signal and outputs the amplified transmission signal to the antenna,
wherein the amplifying device includes
a comb-shaped transistor including a comb-shaped source electrode having a plurality of source fingers,
one or more resistors connected between the source electrode and a ground, and
a plurality of capacitors connected between the source electrode and the ground and separated from each other and arranged in a direction in which the source fingers are arranged.
